(19) United States
(12) Patent Application Publication
(10) Pub. No.: US 2009/0221144 A1
(43) Pub. Date: Sep. 3, 2009

(54) Manufacturing method for nano scale Ge metal structure

(75) Inventors: Ming-Hsin Cheng, HsinChu City (TW); Shih-Chiang Huang, HsinChu City (TW); Wei-Xin Ni, HsinChu City (TW); Guang-Li Luo, HsinChu (TW)

Correspondence Address: BIRCH STEWART KOLASCH & BIRCH, PO BOX 747, FALLS CHURCH, VA, 22040-0747, US

(73) Assignee: National Applied Research Laboratories

(21) Appl. No.: 12/073,243

(22) Filed: Mar. 3, 2008

(51) Int. Cl. H01L 21/4763

(52) U.S. Cl. 438/675; 257/E21.495

(57) ABSTRACT

Manufacturing methods for nano scale Ge include: Form dielectric layer on the substrate surface, then etch the dielectric layer to form openings of three different dimensions, then use chemical vapor deposition process to deposit Ge metal layer to cover the substrate, dielectric layer and the openings; then on the opening of three different dimensions, nano-dot, nano-disk and nano-ring are formed.

### FIELD OF THE INVENTION

The present invention is related to a manufacturing method for nano scale Ge, it specifically relates a manufacturing method for Ge metal structure that can form nano-dot structure, nano-disk structure and nano-ring structure at the same time.

### BACKGROUND OF THE INVENTION

The prior art to form nano scale structure Ge is to use the characteristic difference between dielectric layer, for example, Silicon Dioxide (SiO2), Silicon Nitride (Si3N4), Hafnium Dioxide (HfO2), Aluminum Oxide (Al2O3), etc., and semiconductor such as Silicon (Si) or Germanium (Ge), and chemical vapor deposition process (CVD) is used to deposit directly on dielectric layer the Ge or Si nano-dot; for example, an US Patent No. 20040147098. However, in such method, due to the difficulty in the control of the process temperature, the formed nano-dot will have very different quality and homogeneity; moreover, in each chemical vapor deposition process, only one nano structure can be formed.

As the technology for forming nano structure of US Patent No. 20020148727 and European Patent No. EP1743392, Alkali Metal and Si or Ge is used to form alloy and to precipitate further into nano structure scale Si or Ge. However, the technical field that this technology can be applied to is smaller, that is, it can only be applied to battery or electrode material and it is very difficult to be applied in industries such as: semiconductor industry, optoelectronic industry and/or biosensor industry, etc.

### SUMMARY OF THE INVENTION

One objective of the present invention is to provide a manufacturing method for nano scale Ge metal structure, which can form simultaneously stable quality and homogeneous nano-dot structure.

Another purpose of the present invention is to provide a manufacturing method for nano scale Ge metal structure and in the same time a manufacturing method for forming nano-dot structure, nano-disk structure and nano-ring structure Ge metal structure

Yet another purpose of the present invention is to provide a manufacturing method for nano scale Ge metal structure which can be widely used in for example, semiconductor industry, optoelectronic industry and/or biosensor fields, etc.

Yet another objective of the present invent-ion is to provide a manufacturing method for nano scale Ge metal structure and the method includes: providing a substrate; forming a dielectric layer on the substrate, coating the substrate surface; etching the dielectric layer for forming openings of different dimensions, for example, a first opening, a second opening and a third opening; and performing a chemical vapor deposition process to deposit Ge metal layer on the first opening, the second opening and the third opening so as to form a first Ge metal structure a second Ge metal structure and a third Ge metal structure.

Further another objective of the present invention is to provide a manufacturing method for nano scale Ge metal structure, which includes: providing a Si substrate; using wet cleaning process and 1% HF solution to perform a pre-treatment process on Si substrate; using high temperature furnace to form a 10˜500 nm dielectric layer, for example, Si02, Si3N4, Hf02 on Si substrate; using electron beam direct writing system and active ion micro-lithography process to etch the dielectric layer to form 150˜350 nm first opening, 400˜600 nm second opening and 650˜850 nm third opening; and at 350˜550° C., performing an ultra high vacuum chemical vapor deposition process for 1˜3 hours to deposit a Ge metal material layer, for example, pure Ge metal or Si—Ge alloy on the first opening, second opening and third opening so as to form nano-dot structure, nano-disk structure and nano-disk structure Ge metal structure.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1A˜1E is the cross section flow chart of the manufacturing method of the nano scale Ge metal structure of the embodiment of the present invention.

FIG. 2 is the AFM photo of the nano-dot Ge metal structure of the embodiment of the present invention.

FIG. 3 is the AFM photo of the nano-disk Ge metal structure of the embodiment of the present invention.

FIG. 4 is the AFM photo of the nano-ring Ge metal structure of the embodiment of the present invention.

### DETAILED DESCRIPTION OF THE INVENTION

In the followings, different embodiments will be used to describe the composition, arrangement and step mentioned in this invention; however, they are just examples and are not used to limit the present invention. In addition, “and/or” used in the content disclosed is just for briefing reason; “coating” or “above” description can include two situations of direct contact and non-direct contact.

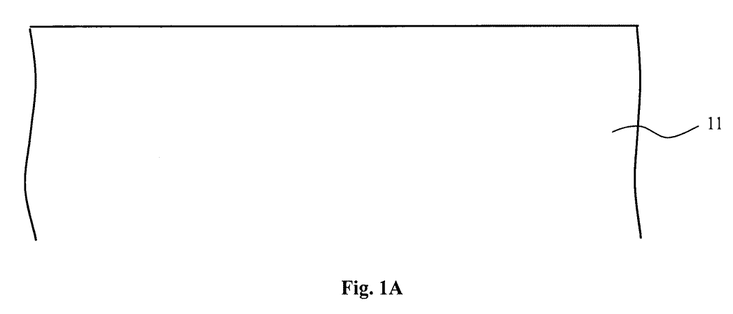

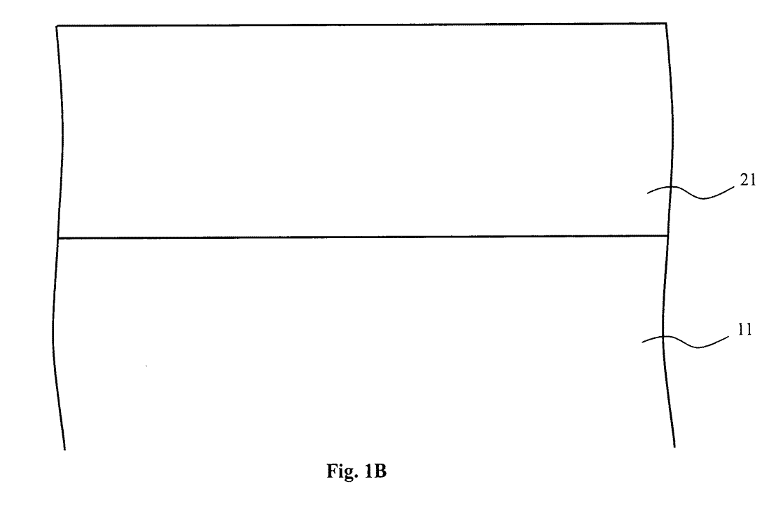

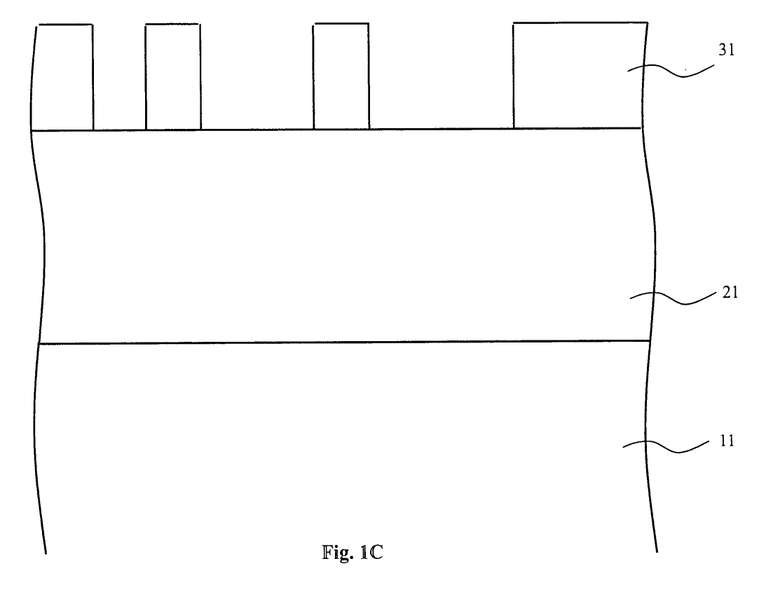

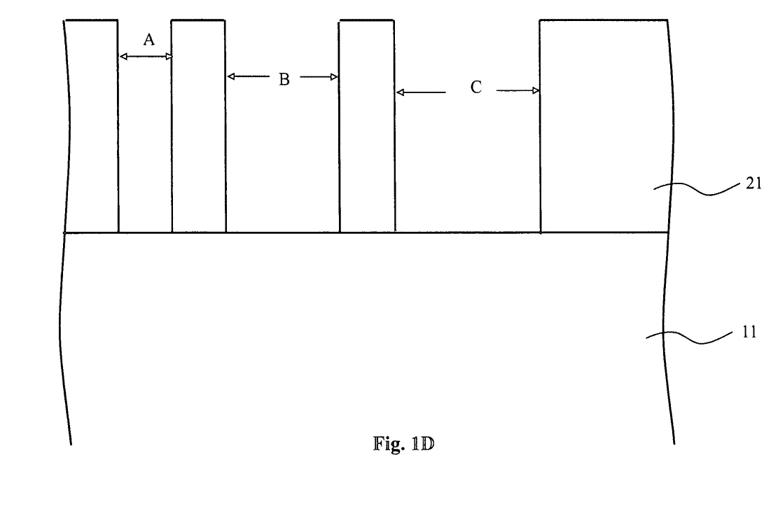

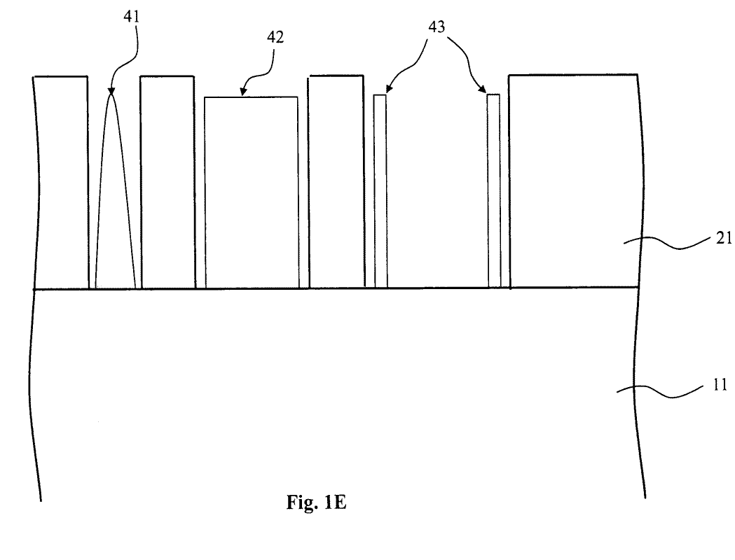

As shown in FIG. 1A˜1E, which is one embodiment of the present invention and is used to describe the manufacturing method of nano scale Ge metal structure of the present invention.

To substrate 11, for example, Si substrate, standard semiconductor wet process will be used first to clean it, then it will be immersed in 1% HF solution to perform pre-treatment process to remove the native oxide on the surface of substrate 11 (not shown in the figure).

Then high temperature furnace is used to perform Atmospheric Pressure Chemical Vapor Deposition (APCVD) on substrate surface to form for example, Si02, Si3N4 and Hf02 with thickness 10˜500 nm of dielectric layer 21; however, the optimum thickness of dielectric layer is 100 nm as shown in FIG. 1B. Then through photo resist coating and microlithography process, patterned photo resist layer 31 is formed on dielectric layer 21 as shown in FIG. 1C.

Then E-beam Direct Writing system, for example, Leica E-beam weprint 200 equipment and Reactive Ion Etching (RIE), for example, TEL TE-5000 equipment are used to perform etching on dielectric layer 12, then the patterned photo resist layer 31 is removed, and openings of three different dimensions A, B, C are thus formed on dielectric layer 21, which include: a dimension in between 150˜350 nm, for example, 320 nm of first opening A; dimension in between 400˜600 nm, for example, 440 nm of second opening B; dimension in between 650˜850 nm, for example 690 nm of third opening C, as shown in FIG. 1D.

At process temperature of 350˜550° C., 13 hours of Ultra-High Vacuum Chemical Vapor Deposition (UHVCVD) process is performed, the better case is 430° C. for 3 hours to deposit Ge metal material on the first opening, second opening and third opening; here the Ge metal material can be pure Ge metal (100% Ge), or metallic alloy that contains Ge, for example, the high composition SiGe alloy (Si50% Ge50%˜Si5% Ge95%, Si1-xGex). The formed metal material, due to different dimensions of the openings, will take different stresses during the deposition process; therefore, nano-dot Ge metal structure 41 will be formed at first opening A, nano-disk Ge metal structure 42 will be formed at second opening B and nano-ring Ge metal structure 43 will be formed at the third opening C.

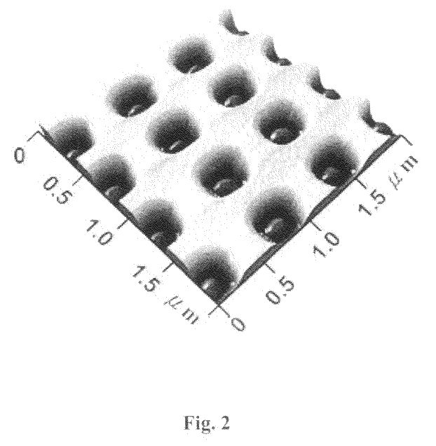

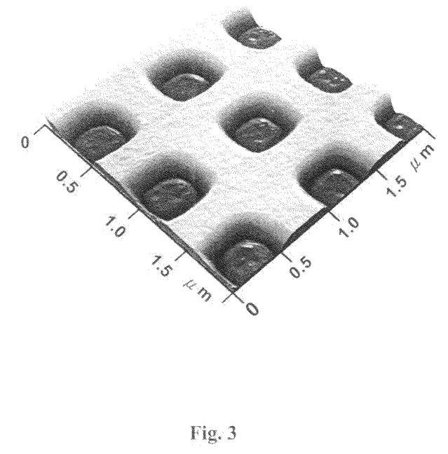

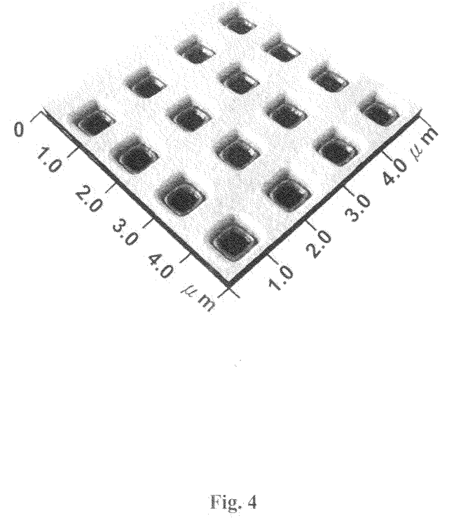

FIG. 2˜4 is the measurement result using Atomic Force Microscope (AFM), on the nano-dot Ge metal structure, nano-disk Ge metal structure and nano-ring Ge metal structure formed by using the Ge metal structure manufacturing method of the present invention. The nano-dot of FIG. 2 is of width 50 nanometer (nm) and height 21 nm; the nano-disk of FIG. 3 is of width 309 nm and height 23 nm; and the nano-ring of FIG. 4 is of width 286 nm and height 30 nm.

1. A manufacturing method for nano scale Ge metal structure, comprising of:
providing a substrate;
forming a dielectric layer on the substrate to coat the substrate surface;
etching the dielectric layer to form a first opening, a second opening and a third opening of different dimensions; and
performing a chemical vapor deposition process to deposit a Ge metal material on the first opening, second opening and third opening so as to form a first Ge metal structure, a second Ge metal structure and a third Ge metal structure.

2. The manufacturing method for nano scale Ge metal structure of claim 1, wherein the substrate is a silicon substrate.

3. The manufacturing method for nano scale Ge metal structure of claim 1, wherein before the formation of the dielectric layer, it further includes pre-treatment process with steps including:
performing a wet cleaning process to clean the substrate; and
providing an acid solution to immerse the substrate.

4. The manufacturing method for nano scale Ge metal structure of claim 3, wherein the acid solution is HF solution.

5. (canceled)

6. The manufacturing method for nano scale Ge metal structure of claim 1, wherein the dielectric layer material is selected from the group consisting of from SiO2, Si3N4, HfO2.

7. The manufacturing method for nano scale Ge metal structure of claim 1, wherein the dielectric layer is of thickness 10˜500 nm.

8. The manufacturing method for nano scale Ge metal structure of claim 1, wherein the dielectric layer is formed by a method of chemical vapor deposition process.

9. The manufacturing method for nano scale Ge metal structure of claim 1, wherein the dielectric layer is formed by high temperature furnace.

10. The manufacturing method for nano scale Ge metal structure of claim 1, wherein the first opening, second opening and third opening are formed by a micro-lithography process.

11. The manufacturing method for nano scale Ge metal structure of claim 10, wherein the micro-lithography process includes e-beam direct writing system and reactive ion etching.

12. The manufacturing method for nano scale Ge metal structure of claim 1, wherein the first opening is of 150˜350 nm.

13. The manufacturing method for nano scale Ge metal structure of claim 1, wherein the second opening is of 400˜600 nm.

14. The manufacturing method for nano scale Ge metal structure of claim 1, wherein the third opening is of 650˜850 nm.

15. The manufacturing method for nano scale Ge metal structure of claim 1, wherein the chemical vapor deposition process is an ultra high vacuum chemical vapor deposition process.

16. The manufacturing method for nano scale Ge metal structure of claim 1, wherein the chemical vapor deposition process is an ultra high vacuum chemical vapor deposition process with a process temperature of 430° C.

17. The manufacturing method for nano scale Ge metal structure of claim 16, wherein the process time of the ultra high vacuum chemical vapor deposition process is three hours.

18. The manufacturing method for nano scale Ge metal structure of claim 1, wherein the Ge metal material layer is of pure Ge material.

19. The manufacturing method for nano scale Ge metal structure of claim 1, wherein the Ge metal material layer is of high composition Si—Ge alloy.

20. The manufacturing method for nano scale Ge metal structure of claim 1, wherein the first Ge metal structure is a nano-dot structure.

21. The manufacturing method for nano scale Ge metal structure of claim 1, wherein the second Ge metal structure is a nano-disk structure.

22. The manufacturing method for nano scale Ge metal structure of claim 1, wherein the third Ge metal structure is a nano-disk structure.
